(19) United States
(12) Patent Application Publication
(10) Pub. No.: US 2025/0190670 A1
(43) Pub. Date: Jun. 12, 2025

(54) ANTENNA DESIGN SYSTEM

(71) Applicant: Quanta Computer Inc., Taoyuan City (TW)

(72) Inventors: Cheng-Yu LIN, Taoyuan City (TW); Mei-Hung KUO, Taoyuan City (TW)

(21) Appl. No.: 18/615,125

(22) Filed: Mar. 25, 2024

(30) Foreign Application Priority Data
Dec. 7, 2023 (TW) 112147659

(51) Int. Cl. G06F 30/39; H01Q 1/38

(52) U.S. Cl. CPC G06F 30/39; H01Q 1/38

(57) ABSTRACT

Provided is an antenna design solution that requires users to input only a small amount of relevant parameters, allowing the automatic generation of the antenna prototype through a generative model. The various components of the antenna prototype are then adjusted to meet the desired results through simulation and boundary adjustment procedures.

### CROSS REFERENCE TO RELATED APPLICATIONS

This application claims priority of Taiwan Patent Application No. 112147659, filed on Dec. 7, 2023, the entirety of which is incorporated by reference herein.

### BACKGROUND OF THE INVENTION

### Field of the Invention

The present invention relates to antenna design, and, in particular, to an antenna design system.

### Description of the Related Art

In practical antenna design, certain software tools, such as High Frequency Structure Simulator (HFSS), Advanced Design System (ADS), Computer Simulation Technology (CST), or Antenna Magus, are often used to simulate antenna specifications and environmental constraints. During the simulation process, a human-designed antenna prototype needs to be input, and the simulation results need to be repeatedly confirmed and manually adjusted until they meet requirements. Additionally, some simulation tools provide optimization functions, allowing the simulation tool to automatically simulate the parts of the antenna prototype that need adjustment. However, the parts to be adjusted, their range, and the amount of change all need to be set up beforehand, making the setup inefficient and requiring considerable time to analyze whether the results of all variables meet requirements.

Therefore, there is a need for an antenna design system and method that can overcome the aforementioned limitations, making the antenna design process more efficient.

### BRIEF SUMMARY OF THE INVENTION

An embodiment of the present disclosure provides an antenna design system. The antenna design system includes a display unit, an input unit, a storage unit, and a processing unit. The processing unit loads a program from the storage unit and runs the program to execute the following steps. The processing unit receives a design parameter set from the input unit. The processing unit generates an antenna prototype using a generative model that corresponds to the design parameter set. The processing unit causes the display unit to display the antenna prototype. The processing unit receives, from the input unit, one or more tuning parameter sets, among which a first tuning parameter set includes a first region parameter set and a first frequency band that correspond to a first component of the antenna prototype. The processing unit performs a simulation process on the first component of the antenna prototype based on the first frequency band to obtain the frequency offset index of the first component. The processing unit checks whether the frequency offset index of the first component satisfies a no-offset condition. In response to the frequency offset index of the first component not satisfying the no-offset condition, the processing unit adjusts the scale of the first component based on the frequency offset index of the first component and the first region parameter set. The processing unit iteratively executing the steps of performing the simulation process on the first component and adjusting the scale of the first component until the frequency offset index of the first component satisfies the no-offset condition.

In an embodiment, the second tuning parameter set includes a second region parameter set and a second frequency band that correspond to a second component of the antenna prototype, and the third tuning parameter set includes a third region parameter set and a third frequency band that correspond to a third component of the antenna prototype. Additionally, the processing unit further executes the following steps. The processing unit performs the simulation process on the second component of the antenna prototype based on the second frequency band to obtain the frequency offset index of the second component. The processing unit checks whether the frequency offset index of the second component satisfies the no-offset condition. In response to the frequency offset index of the second component not satisfying the no-offset condition, the processing unit adjusts the scale of the second component based on the frequency offset index of the second component and the second region parameter set. The processing unit iteratively executing the steps of performing the simulation process on the second component and adjusting the scale of the second component until the frequency offset index of the second component satisfies the no-offset condition. The processing unit performs the simulation process on the third component of the antenna prototype based on the third frequency band to obtain the frequency offset index of the third component. The processing unit checks whether the frequency offset index of the third component satisfies the no-offset condition. In response to the frequency offset index of the third component not satisfying the no-offset condition, the processing unit adjusts the scale of the third component based on the frequency offset index of the third component and the third region parameter set. The processing unit iteratively executing the steps of performing the simulation process on the third component and adjusting the scale of the third component until the frequency offset index of the third component satisfies the no-offset condition.

In an embodiment, the first frequency band is 2.4 GHz, the second frequency band is 5 GHz, and the third frequency band is 6 GHz.

In an embodiment, the fourth tuning parameter set includes a fourth region parameter set corresponding to a fourth component of the antenna prototype and an impedance matching identifier. Additionally, the processing unit further execute the following steps. The processing unit performs the simulation process on the antenna prototype to obtain the return loss index of the antenna prototype. The processing unit adjusts the scale of the fourth component. The processing unit performs the simulation process on the antenna prototype again to obtain another return loss index of the antenna prototype. The processing unit determines the adjustment direction by comparing the return loss index with the other return loss index. The processing unit adjusts the scale of the fourth component based on the adjustment direction.

In an embodiment, the first component corresponds to a bounding box, and the first region parameter set defines a first region. Additionally, the processing unit further executes the following steps to adjust the scale of the first component. The processing unit determines the adjustment direction based on the frequency offset index. The processing unit calculates the first distance between the component boundary on one side of the bounding box and the region boundary on the same side of the first region. The processing unit determines the step size based on the first distance. The processing unit updates the component boundary according to the adjustment direction and the step size.

In an embodiment, the processing unit further records the current position of the component boundary before updating the component boundary. After updating the component boundary, the processing unit further executes the following steps. Based on the bounding box of the first component and another bounding box that corresponds to another component of the antenna prototype, the processing unit determines whether the first component collides with the other component through a collision detection process. If it is determined that the first component collides with the other component, the processing unit reverts the component boundary of the first component to the recorded current position before updating.

In an embodiment, the processing unit further uses the object detection model to obtain the bounding box that corresponds to the first component in the antenna prototype. In another embodiment, the first tuning parameter set further includes the bounding box.

In an embodiment, the design parameter set further includes a specification parameter and an environment parameter.

In an embodiment, the processing unit further trains a generative adversarial network using a real image set that corresponds to the design parameter set, to obtain the generative model.

An embodiment of the present disclosure provides an antenna design method.

The method is implemented by the processing unit of a computer system. The method includes the step of receiving a design parameter set from the input unit. The method further includes the step of generating an antenna prototype using a generative model that corresponds to the design parameter set. The method further includes the step of causing the display unit to display the antenna prototype. The method further includes the step of receiving, from the input unit, one or more tuning parameter sets, among which a first tuning parameter set includes a first region parameter set and a first frequency band that correspond to a first component of the antenna prototype. The method further includes the step of performing a simulation process on the first component of the antenna prototype based on the first frequency band to obtain the frequency offset index of the first component. The method further includes the step of checking whether the frequency offset index of the first component satisfies a no-offset condition. The method further includes the step of adjusting the scale of the first component based on the frequency offset index of the first component and the first region parameter set, in response to the frequency offset index of the first component not satisfying the no-offset condition. The method further includes iteratively executing the steps of performing the simulation process on the first component and adjusting the scale of the first component until the frequency offset index of the first component satisfies the no-offset condition.

In an embodiment, the second tuning parameter set includes a second region parameter set and a second frequency band that correspond to a second component of the antenna prototype, and the third tuning parameter set includes a third region parameter set and a third frequency band that correspond to a third component of the antenna prototype. Additionally, the method further includes the step of performing the simulation process on the second component of the antenna prototype based on the second frequency band to obtain the frequency offset index of the second component. The method further includes the step of checking whether the frequency offset index of the second component satisfies the no-offset condition. The method further includes the step of adjusting the scale of the second component based on the frequency offset index of the second component and the second region parameter set, in response to the frequency offset index of the second component not satisfying the no-offset condition. The method further includes iteratively executing the steps of performing the simulation process on the second component and adjusting the scale of the second component until the frequency offset index of the second component satisfies the no-offset condition. The method further includes the step of performing the simulation process on the third component of the antenna prototype based on the third frequency band to obtain the frequency offset index of the third component. The method further includes the step of checking whether the frequency offset index of the third component satisfies the no-offset condition. The method further includes the step of adjusting the scale of the third component based on the frequency offset index of the third component and the third region parameter set, in response to the frequency offset index of the third component not satisfying the no-offset condition. The method further includes iteratively executing the steps of performing the simulation process on the third component and adjusting the scale of the third component until the frequency offset index of the third component satisfies the no-offset condition.

In an embodiment, the fourth tuning parameter set includes a fourth region parameter set corresponding to a fourth component of the antenna prototype and an impedance matching identifier. Additionally, the method further includes the step of performing the simulation process on the antenna prototype to obtain the return loss index of the antenna prototype. The method further includes the step of adjusting the scale of the fourth component. The method further includes the step of performing the simulation process on the antenna prototype again to obtain another return loss index of the antenna prototype. The method further includes the step of determining the adjustment direction by comparing the return loss index with the other return loss index. The method further includes the step of adjusting the scale of the fourth component based on the adjustment direction.

In an embodiment, the first component corresponds to a bounding box, and the first region parameter set defines a first region. Additionally, the step of adjusting the scale of the first component further includes determining the adjustment direction based on the frequency offset index, calculating the first distance between the component boundary on one side of the bounding box and the region boundary on the same side of the first region, determining the step size based on the first distance, and updating the component boundary according to the adjustment direction and the step size.

In an embodiment, the step of adjusting the scale of the first component further includes recording the current position of the component boundary before updating the component boundary. The step of adjusting the scale of the first component further includes, after updating the component boundary, determining, based on the bounding box of the first component and another bounding box that corresponds to another component of the antenna prototype, whether the first component collides with the other component through a collision detection process. The step of adjusting the scale of the first component further includes, if it is determined that the first component collides with the other component, reverting the component boundary of the first component to the recorded current position before updating. In an embodiment, the method further includes the step of using the object detection model to obtain the bounding box that corresponds to the first component in the antenna prototype. In another embodiment, the first tuning parameter set further includes the bounding box.

In an embodiment, the method further includes the step of training a generative adversarial network using a real image set that corresponds to the design parameter set, to obtain the generative model.

The antenna design solution provided herein automatically generates antenna prototypes through a generative model, requiring only a small amount of relevant parameters input by the user. Through simulation process and boundary adjustment process, the components of the antenna prototype are adjusted to meet the desired results. This not only saves time spent on human verification and manual adjustments but also allows the antenna prototypes produced by the antenna design system to be more diverse and not limited by human imagination. Therefore, through the antenna design solution provided herein, both the efficiency and innovation of the antenna design process can be significantly enhanced.

### BRIEF DESCRIPTION OF THE DRAWINGS

The present invention can be more fully understood by reading the subsequent detailed description and examples with references made to the accompanying drawings, wherein:

FIG. 1 is a system block diagram of an antenna design system, according to an embodiment of the present disclosure;

FIG. 2 is a flow diagram of an antenna design method, according to an embodiment of the present disclosure;

FIG. 3 shows a schematic example of an antenna prototype, according to an embodiment of the present disclosure;

FIG. 4 is the flow diagram of steps for adjusting the scale of the second component and the third component of the antenna prototype, according to an embodiment of the present disclosure;

FIG. 5 is the flow diagram of steps for adjusting components affecting the depth of impedance matching, according to an embodiment of the present disclosure;

FIG. 6 shows a schematic example of the spatial relationship between the bounding box corresponding to the first component of the antenna prototype and the first region;

FIG. 7 is a flow diagram illustrating more details of steps for adjusting the scale of the first component, according to an embodiment of the present disclosure;

FIG. 8 is a flow diagram based on the antenna component scale adjustment steps of FIG. 7, further incorporating steps of a collision detection mechanism, according to an embodiment of the present disclosure; and

FIG. 9 is an architecture diagram of a generative adversarial network (GAN) 900, according to an embodiment of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

In each of the following embodiments, the same reference numbers represent identical or similar elements or components.

It must be understood that the terms “including” and “comprising” are used in the specification to indicate the existence of specific technical features, numerical values, method steps, process operations, elements and/or components, but do not exclude additional technical features, numerical values, method steps, process operations, elements, components, or any combination of the above.

Ordinal terms used in the claims, such as “first,” “second,” “third,” etc., are only for convenience of explanation, and do not imply any precedence relation between one another.

The descriptions of embodiments regarding devices or systems below are also applicable to embodiments of methods, and vice versa.

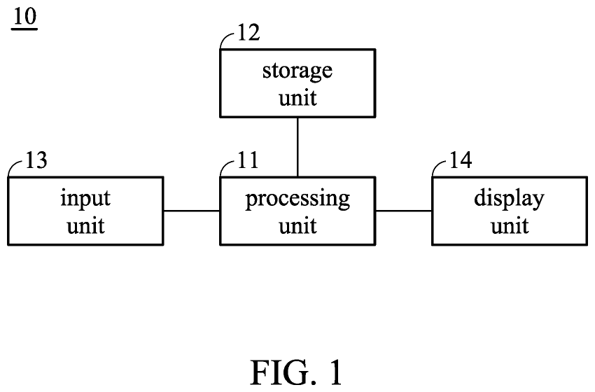

FIG. 1 is a system block diagram of an antenna design system 10, according to an embodiment of the present disclosure. The antenna design system 10 can be any computer system capable of computational tasks, such as a personal computer (e.g., desktop or laptop), server computer, tablet, or smartphone, capable of processing data, but the present disclosure is not limited thereto. As shown in FIG. 1, the antenna design system 10 may include a processing unit 11, a storage unit 12, an input unit 13, and a display unit 14. The processing unit 11 is communicable with the storage unit 12, the input unit 13, and the display unit 14 via various wired or wireless communication interfaces, such as system buses, High Definition Multimedia Interface (HDMI), DisplayPort (DP), embedded DisplayPort (eDP), Universal Serial Bus (USB), USB Type-C, Thunderbolt, Digital Video Interface (DVI), 5th Generation (5G) wireless systems, Bluetooth, Wi-Fi, Near Field Communication (NFC), and/or the combination thereof.

The processing unit 11 may include general-purpose or specialized hardware components for executing instructions, such as Central Processing Unit (CPU), Graphics Processing Unit (GPU), Neural-network Processing Unit (NPU), microprocessor, microcontroller, Application Specific Integrated Circuit (ASIC), Field Programmable Gate Array (FPGA), System on a Chip (SoC), and/or the combination thereof, but the present disclosure is not limited thereto. The processing unit 11 loads programs from the storage unit 12 to execute an antenna design method, which will be elaborated later.

The storage unit 12 can be any device with non-volatile memory (e.g., read-only memory (ROM), electrically-erasable programmable read-only memory (EEPROM), flash memory, non-volatile random access memory (NVRAM)), such as hard disk drives (HDD), solid-state drives (SSD), or optical disks, but the present disclosure is not limited thereto. The storage unit 12 may be fully or partially deployed locally (i.e., on the device where the processing unit 11 is located) or remotely. In embodiments of the present disclosure, the storage unit 12 stores a program containing multiple instructions for implementing the antenna design method described above. When loading this program from the storage unit 12, the processing unit 11 executes these instructions to implement the antenna design method. Additionally, the storage device 12 further stores data required for executing the method or generated during the process.

The input unit 13 can be any device capable of receiving external input data, such as a mouse, keyboard, keypad, console, touch display component, or voice input device, but the present disclosure is not limited thereto. In embodiments of the present disclosure, the input unit 13 translates the parameters input by the user into analog or digital signals and then transmits them to the processing unit 11. Various types and functions of these input parameters will be elaborated later.

The display unit 14 can be any type of display device for presenting visible information, such as LCD displays, LED displays, OLED displays, plasma displays, e-paper, or projection devices, but the present disclosure is not limited thereto. In embodiments of the present disclosure, the processing unit 11 provides a user interface (UI) for interaction with the user. The user interface can be a graphical user interface (GUI), a command line interface (CLI), or a touch interface, but the present disclosure is not limited thereto. The processing unit 11 transmits the user interface to the display unit 14 in the form of analog or digital signals so that the display unit 14 can present the user interface to the user.

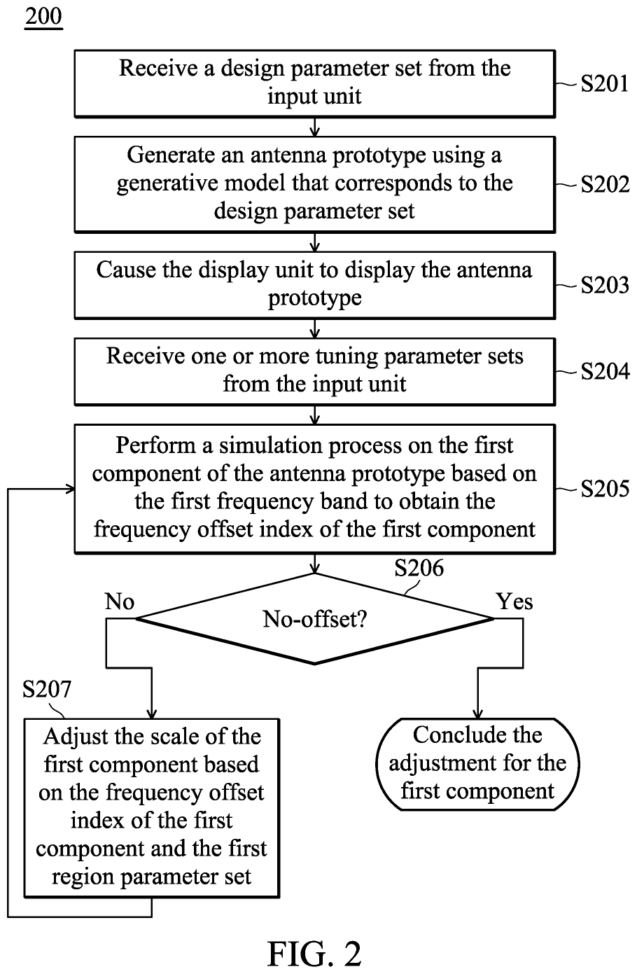

FIG. 2 is a flow diagram of an antenna design method 200, according to an embodiment of the present disclosure. The antenna design method 200 is implemented by the processing unit 11 of the antenna design system 10 illustrated in FIG. 1. As shown in FIG. 2, the antenna design method 200 may include steps S201-S207.

In step S201, a design parameter set is received from the input unit 13.

The design parameter set can include various parameters related to antenna design considerations or variations. In an embodiment, the design parameter set may include specification parameters and environmental parameters. Specification parameters refer to parameters related to the antenna object itself, such as antenna substrate material (e.g., FR4, PTFE, RO4003, Rogers 4350B, aluminum oxide ceramics, or other certain materials), antenna size (e.g., 40*5*0.4 mm, 40*40*1 mm, or other certain sizes), antenna type (e.g., monopole antenna, dipole antenna, patch antenna, loop antenna, planar inverted F antenna (PIFA), chip antenna, or other certain types). Environmental parameters refer to parameters related to the external environment where the antenna is located, such as weather conditions (e.g., temperature, humidity, wind speed, etc.), the product in which the antenna is installed (e.g., wireless routers, laptops, smartphones, satellite TVs, car navigation systems, etc.), and its placement position (e.g., on both sides of the camera on a laptop screen).

In an embodiment, before step S201, relevant textual messages prompting the user to input the design parameter set can be presented through the user interface (although not mandatory), such as “Select antenna substrate material” or “Input antenna dimensions”, but the present disclosure is not limited thereto. Additionally, UI elements or widgets such as checkboxes, toggle switches, drop-down lists, text boxes, or the like can be provided on the user interface to facilitate user input of the design parameter set, although the specific design configuration of the user interface is not limited by the present disclosure.

In step S202, an antenna prototype is generated using the generative model that corresponds to the design parameter set.

The generative model can be any well-established text-to-image or image-to-image model based on generative artificial intelligence (generative AI), such as Stable Diffusion, Control Net, Grounded Language-to-Image Generation (GLIGEN), DALL-E. Alternatively, generative model can be a custom-built model constructed by developers. The type of generative model is not limited by the present disclosure. Since the generative model can be pre-trained on a large dataset of antenna data (i.e., 2D antenna images or 3D antenna models) using unsupervised learning during its construction/training phase, during its usage phase (e.g., step S203), no additional images need to be input, and the antenna prototype can be automatically generated. Additionally, depending on the dataset used during the construction/training phase, the antenna prototype generated by the generative model can be a 2D image or a 3D model. The dimensionality of the antenna prototype is not limited in the present disclosure. Furthermore, the generative model can be trained locally on the device or trained elsewhere (e.g., on a server) and obtained via the network (e.g., downloaded from the cloud), storage media (e.g., external hard drive), or other communication interfaces, but the present disclosure is not limited thereto.

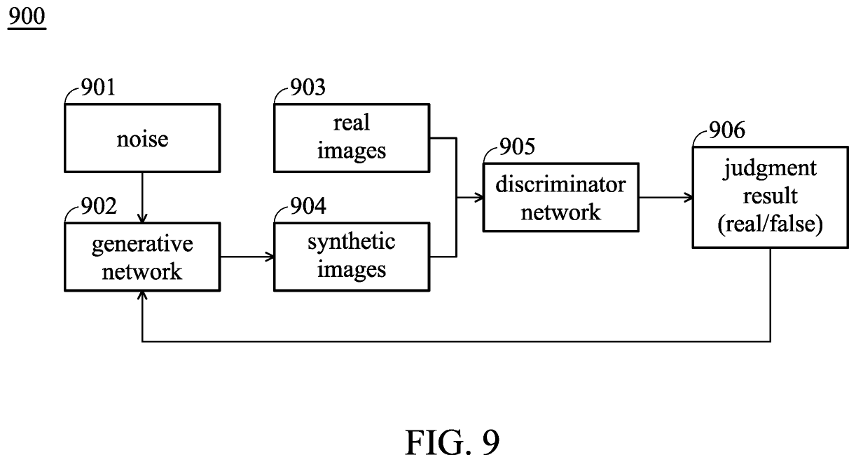

In an embodiment, a generative adversarial network (GAN) can be trained using a variety of design parameter sets (such as combinations of the aforementioned specification parameters and environmental parameters) to obtain the generative model. The architecture and training of the generative adversarial network will be elaborated later with reference to FIG. 9.

In step S203, the display unit 14 is caused to show the antenna prototype generated by the generative model.

More specifically, in step S203, the antenna prototype can be presented within the user interface, which is then displayed by the display unit 14. The purpose of this step is to allow users to decide on the tuning parameters needed for subsequent steps based on the current antenna prototype they see.

In step S204, one or more tuning parameter sets are received from the input unit 13.

Each tuning parameter set received in step S204 consists of multiple tuning parameters, and corresponds to one of the components of the antenna prototype. That is, each tuning parameter set includes parameters used to tune its corresponding component. Among all antenna components, some may affect the performance of the antenna in certain frequency bands, while others may be related to the depth of impedance matching of the antenna.

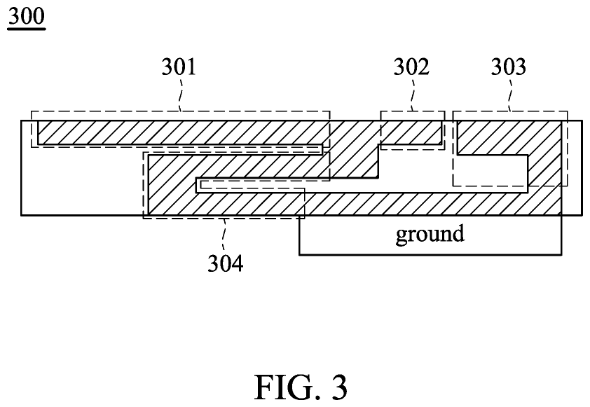

FIG. 3 shows a schematic example of an antenna prototype 300, according to an embodiment of the present disclosure. As shown in FIG. 3, the antenna prototype 300 includes components 301, 302, 303, and 304. In this example, it is assumed that component 301 affects the 2.4 GHz frequency band (typically referring to 2.4-2.48 GHZ), component 302 affects the 5 GHz frequency band (typically referring to 5.15-5.85 GHZ), component 303 affects the 6 GHz frequency band (typically referring to 5.92-7.12 GHZ), while component 304 is related to the impedance matching depth of the antenna 300.

Each tuning parameter set received in step S204 includes a corresponding region parameter set. The region parameter set is used to define the position and extent of the substrate carrying the respective antenna component. Since antenna components cannot exceed the substrate's boundaries, the region parameter set can also be seen as constraints for the subsequent scaling adjustments to the antenna components. Typically, adjustments to antenna components only consider their two larger scales, such as length and width (or height), while thickness is disregarded. The same applies to the substrate carrying the antenna components. The shape of the substrate plane is usually rectangular, and there are many ways to represent a rectangle in space, so the region parameter set can take on various forms. For example, the region parameter set could consist of the coordinates of any vertex of the substrate plane plus the length and width of the substrate plane. Alternatively, it could consist of the coordinates of all vertices of the substrate plane (i.e., the coordinates of the top-left, bottom-left, top-right, and bottom-right vertices), or it could consist of the coordinates of the two vertices on the diagonal (such as the combination of the top-left and bottom-right vertices or the combination of the bottom-left and top-right vertices), but the present disclosure is not limited thereto.

The tuning parameter set received in step S204 includes at least one corresponding antenna component that affects the performance of a certain frequency band, such as one of the components 301-303 in FIG. 3. This tuning parameter set will be referred to as the “first tuning parameter set” thereafter, with its corresponding antenna component, region parameter set, and frequency band referred to as the “first component,” “first region parameter set,” and “first frequency band,” respectively. Therefore, the first tuning parameter set includes the first component's first region parameter set and the first frequency band.

In step S205, a simulation process is performed on the first component of the antenna prototype based on the first frequency band to obtain the frequency offset index of the first component.

The simulation process can be performed using various mature antenna simulation software tools such as High Frequency Structure Simulator (HFSS), Advanced Design System (ADS), Computer Simulation Technology (CST), or Antenna Magus. More specifically, these software tools often support scripting languages like Python, Visual Basic, or MATLAB, or provide application programming interfaces (APIs) for accessing simulation functionalities such as electromagnetic field simulation, frequency analysis, impedance matching, ray tracing, mode analysis, power distribution, among others.

The frequency offset index can be any measure indicating the difference between the actual output frequency of the antenna component and the expected frequency, such as frequency offset, frequency offset percentage, or frequency offset error, but the present disclosure is not limit thereto. From these indexes, it can be determined whether the antenna component is operating at a frequency that is too high (e.g., when the index is above a certain threshold), a frequency that is too low (e.g., when the index is below a certain threshold), or it has no frequency offset (e.g., if the index falls within a certain range). Depending on the design of the simulation software, the frequency offset index could also directly indicate whether the antenna component has a high-frequency offset, a low-frequency offset, or no frequency offset as a categorical variable.

In step S206, the frequency offset index of the first component is checked to determine if it satisfies a no-offset condition (i.e., the first component does not exhibit a frequency that is either too high or too low). If the frequency offset index of the first component satisfies the no-offset condition, the adjustment for the first component is concluded. Otherwise, the method proceeds to step S207.

In step S207, the scale of the first component, such as length, width, or height, is adjusted based on the frequency offset index of the first component and the first region parameter set. Then, the method returns to step S205.

More specifically, the scale adjustment may involve modifying the scale attribute values in the corresponding data structure of the first component. Since frequency is usually inversely related to the scale of the antenna component, if the frequency offset index shows that the first component exhibits a frequency that is too high, step S207 would elongate the scale of the first component. Conversely, if the frequency offset index indicates that the first component exhibit a frequency that is too low, step S207 would shorten the scale of the first component. As mentioned earlier, the region parameter set can be seen as constraints on the scale adjustment of antenna components. Therefore, elongating the scale of the first component in step S207 cannot cause the first component to exceed the range defined by the first region parameter set.

The steps S205 to S207 described above are executed iteratively until the frequency offset index of the first component satisfies the no-offset condition.

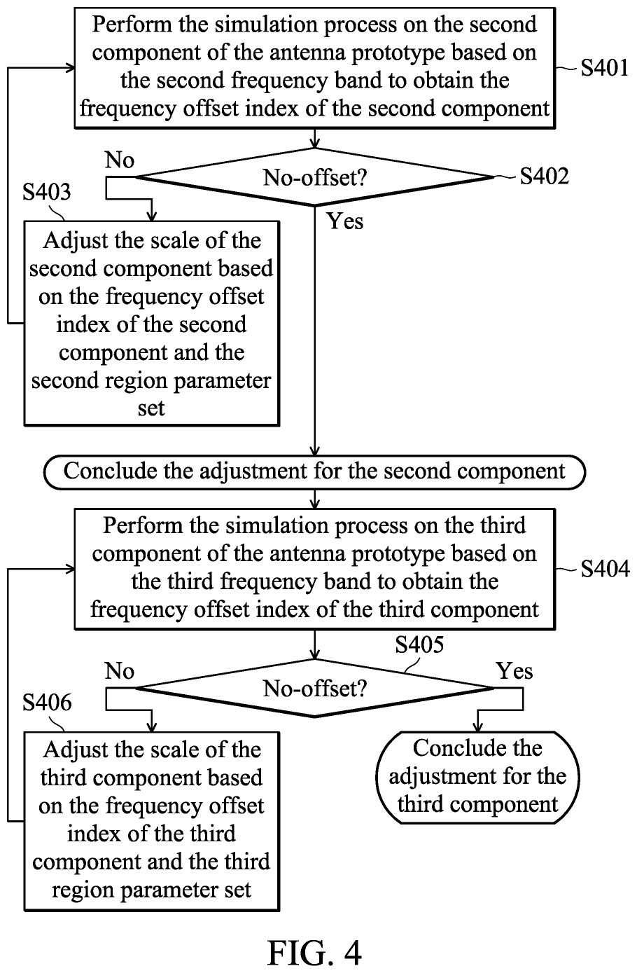

The steps S205 to S207 described above involve adjusting the scale of only the first component. In some implementations, after adjusting the scale of that particular component, the scales of other components are adjusted sequentially. This will be further explained with reference to FIG. 4.

FIG. 4 is the flow diagram of steps S401 to S406 for adjusting the scale of the second component and the third component of the antenna prototype, according to an embodiment of the present disclosure. In this embodiment, the second tuning parameter set among the tuning parameter sets received in step S204 includes the second region parameter set of the second component of the antenna prototype and the second frequency band, while the third tuning parameter set includes the third region parameter set of the third component of the antenna prototype and the third frequency band. Steps S401 to S406 may be executed after the completion of adjustments to the first component in the antenna design method 200.

In step S401, a simulation process is performed on the second component of the antenna prototype based on the second frequency band to obtain the frequency offset index of the second component. Since the simulation process and frequency offset index have been detailed earlier, further elaboration is omitted.

In step S402, the frequency offset index of the second component is checked to determine if it satisfies the no-offset condition (i.e., the second component does not exhibit a frequency that is either too high or too low). If the frequency offset index of the second component satisfies the no-offset condition, the adjustment of the second component is concluded. Otherwise, the method proceeds to step S403.

In step S403, based on the frequency offset index of the second component and the second region parameter set, the scale of the second component, such as length, width, or height, is adjusted. Then, the method returns to step S401.

More specifically, if the frequency offset index indicates that the second component exhibits a frequency that is too high, step S403 will elongate the scale of the second component. Conversely, if the frequency offset index indicates that the second component exhibits a frequency that is too low, step S403 will shorten the scale of the second component. Additionally, elongating the scale of the second component in step S403 cannot cause the second component to exceed the range defined by the second region parameter set.

The above steps S401-S403 will be repeated until the frequency offset index of the second component satisfies the no-offset condition. Then, the method proceeds to step S404.

In step S404, the simulation process is performed on the third component of the antenna prototype based on the third frequency band to obtain the frequency offset index of the third component. Since the simulation process and frequency offset index have been detailed earlier, further elaboration is omitted.

In step S405, the frequency offset index of the third component is checked to determine if it satisfies the no-offset condition (i.e., the third component does not exhibit a frequency that is either too high or too low). If the frequency offset index of the third component satisfies the no-offset condition, the adjustment of the third component is concluded. Otherwise, the method proceeds to step S406.

In step S406, based on the frequency offset index of the third component and the third region parameter set, the scale of the third component, such as length, width, or height, is adjusted. Then, the method returns to step S404.

More specifically, if the frequency offset index indicates that the third component exhibits a frequency that is too high, step S406 will elongate the scale of the third component. Conversely, if the frequency offset index indicates that the third component exhibits a frequency that is too low, step S406 will shorten the scale of the third component. Additionally, elongating the scale of the third component in step S406 cannot cause the third component to exceed the range defined by the third region parameter set.

The above steps S404 to S406 are repeatedly executed until the frequency offset index of the third component satisfies the no-offset condition.

In an embodiment, the first frequency band affected by the first component targeted by steps S205-S207 is 2.4 GHz, the second frequency band affected by the second component targeted by steps S401-S403 is 5 GHz, the third frequency band affected by the third component targeted by steps S404-S406 is 6 GHz. That is, in this embodiment, adjustments to antenna components affecting the performance in each frequency band follow the sequence of “2.4 GHz->5 GHz-6 GHz”.

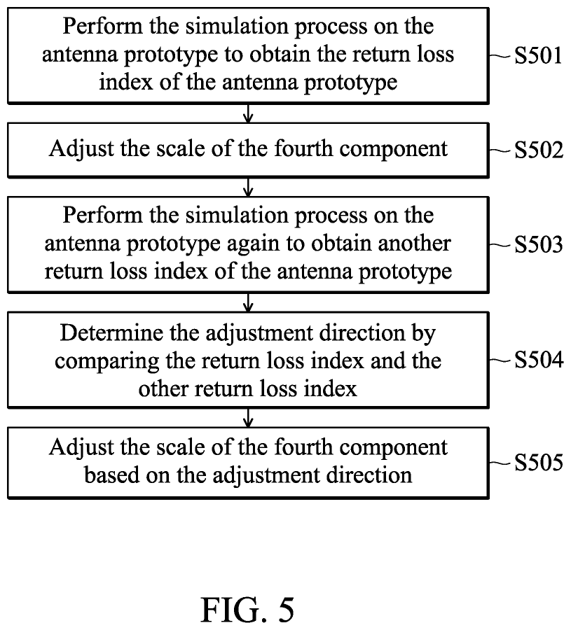

In the described steps S205-S207 and S401-S406, adjustments are made only to the antenna components affecting the performance in each frequency band. In some embodiments, after adjusting these components, further adjustments may be made to the scale of components affecting the depth of impedance matching. Further elaboration will be provided with reference to FIG. 5.

FIG. 5 is the flow diagram of steps S501-S505 for adjusting components affecting the depth of impedance matching, according to an embodiment of the present disclosure. In this embodiment, the fourth tuning parameter set among the tuning parameter sets received in step S204 includes the fourth region parameter set of the antenna prototype, as well as an impedance matching identifier.

In step S501, the simulation process is performed on the antenna prototype to obtain the return loss index of the antenna prototype

The return loss refers to the degree to which a signal is reflected back after entering the antenna. Its value can be, for example, the reflection coefficient, scattering parameters (S-parameters), or Voltage Standing Wave Ratio (VSWR), but the present disclosure is not limited thereto. The return loss index obtained in step S501 can be the average return loss of the entire antenna over multiple frequency bands, or it can be focused on certain frequency bands, or it can be a categorical variable indicating whether the average return loss of the entire antenna or individual frequency bands meets requirements, but the present disclosure is not limited thereto.

In step S502, adjust (i.e., elongate or shorten) the scale of the fourth component, such as length, width, or height.

In step S503, the simulation process is performed on the antenna prototype again to obtain another reflection loss index for the antenna prototype (after adjustment in step S502).

In step S504, the adjustment direction is determined by comparing the reflection loss index obtained in step S501 with the other reflection loss index obtained in step S503.

For example, suppose that in step S502, the adjustment of the fourth component scale is elongation. If the other reflection loss index obtained in step S503 is significantly better than the reflection loss index obtained in step S501 (e.g., the difference between the two is greater than a certain threshold), then continue with the elongation adjustment direction. However, if the other reflection loss index obtained in step S503 is significantly worse than the reflection loss index obtained in step S501, then change the adjustment direction to contraction. Conversely, if in step S502, the adjustment of the fourth component scale is contraction, and the other reflection loss index obtained in step S503 is significantly better than the reflection loss index obtained in step S501, then continue with the contraction adjustment direction. If the other reflection loss index obtained in step S503 is significantly worse than the reflection loss index obtained in step S501, then change the adjustment direction to elongation.

In step S505, the scale of the fourth component is adjusted according to the adjustment direction.

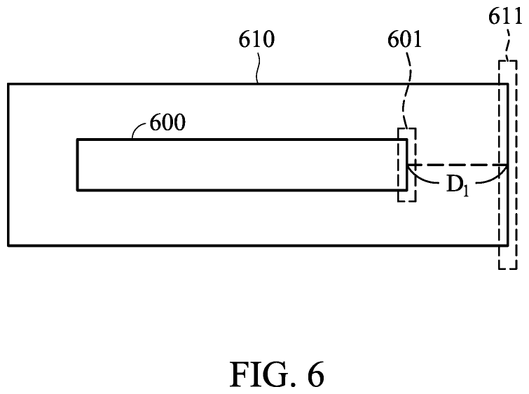

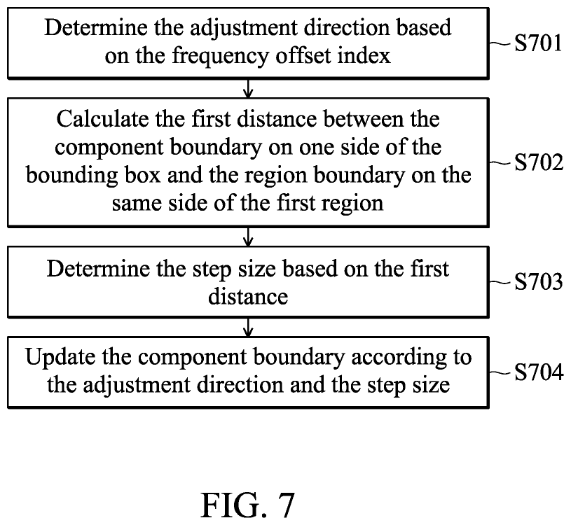

In an embodiment, the magnitude of the scale adjustment for the first component in step S207 depends on the distance between the first component and the substrate boundary. The longer this distance, the greater the potential extension and the smaller the potential contraction of the first component. Therefore, as this distance increases, the extension magnitude in step S207 increases while the contraction magnitude decreases. Conversely, as this distance decreases, the extension magnitude in step S207 decreases while the contraction magnitude increases. Further details regarding this embodiment will be provided with reference to FIGS. 6 and 7.

FIG. 6 shows a schematic example of the spatial relationship between the bounding box 600 corresponding to the first component of the antenna prototype and the first region 610. The first region 610 refers to the region defined by the first region parameter set on the substrate plane. FIG. 7 is a flow diagram illustrating more details of steps S701-S704 for adjusting the scale of the first component, according to an embodiment of the present disclosure. Please refer to both FIGS. 6 and 7 for a better understanding of the embodiments disclosed herein.

In step S701, the adjustment direction is determined based on the frequency offset index. More specifically, if the frequency offset index indicates that the first component exhibits a frequency that is too high, the adjustment direction is elongation. Conversely, if the frequency offset index indicates that the first component exhibits a frequency that is too low, the adjustment direction is contraction.

In step S702, the first distance D1, between the component boundary 601 on one side of the bounding box 600 (in the example of FIG. 6, it's the right side) and the region boundary 611 on that side of the first region 610, is calculated.

In step S703, the step size is determined based on the first distance D1.

As mentioned earlier, if the adjustment direction is elongation, the larger the first distance D1, the larger the step size. The following <Table 1> shows the mapping relationship between the first distance D1 and the step size, in an embodiment where the adjustment direction is elongation.

TABLE 1

| First Distance D₁ | | Step Size | |
|---|---|---|---|
| <0.5 | mm | 0 (no adjustment) | |
| 0.5-1.5 | mm | 0.1 | mm |
| 1.5-4 | mm | 0.3 | mm |
| 4-9 | mm | 1 | mm |
| >9 | mm | 2 | mm |

Conversely, if the adjustment direction is contraction, the larger the first distance D1, the smaller the step size. Further examples are not provided here.

In step S704, the component boundary 601 is updated based on the adjustment direction and the step size.

Likewise, steps S701-S704 can be applied to other components of the antenna prototype that affect the performance in different frequency bands, such as the aforementioned second and third components.

In an embodiment, the bounding box 600 depicted in FIG. 6 is obtained using an object detection model. The object detection model can be based on convolutional neural networks (CNNs), and its training process may involve acquiring labeled data, selecting loss functions, and configuring optimization algorithms, among other well-known practices, but the present disclosure is not limited thereto. Additionally, the object detection model can be trained locally on the device or pre-trained on other computing devices (such as servers) and then obtained via a network (e.g., downloaded from the cloud), storage media (e.g., external hard drive), or other communication interfaces, but the present disclosure is not limited thereto. In another embodiment, the bounding box is included in the first tuning parameter set received in step S204. That is, the bounding box 600, similar to the first region 610, can be parameters input by the user through input unit 13 of the antenna design system 10.

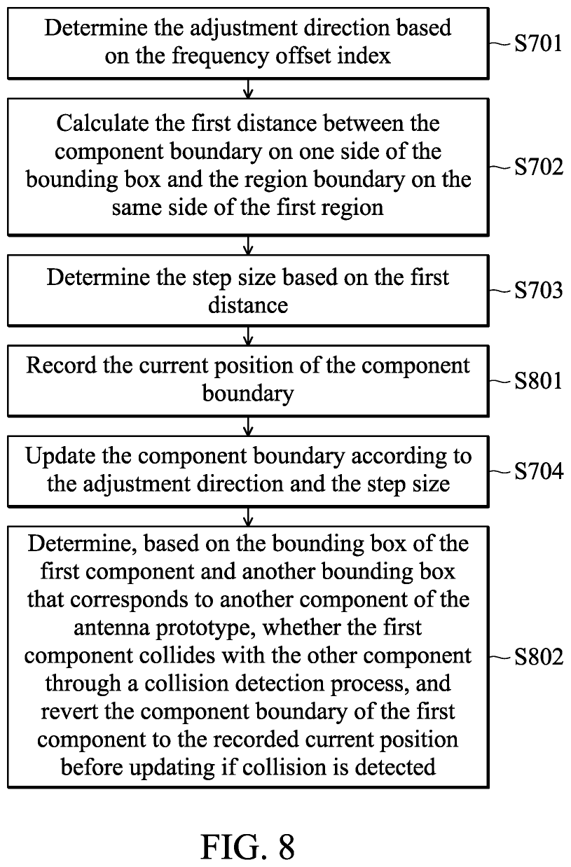

Adjusting the scale of antenna components may result in overlapping or connectivity with another component. Therefore, in an embodiment, collision detection mechanisms are incorporated during the adjustment of antenna component scales. Further elaboration for this embodiment will be provided with reference to FIG. 8.

FIG. 8 is a flow diagram based on the antenna component scale adjustment steps of FIG. 7, further incorporating steps S801 and S802 of a collision detection mechanism, according to an embodiment of the present disclosure. As shown in FIG. 8, before step S704, there is an additional step S801, which records the current position of the component boundary. After step S704, there is an additional step S802, which involves determining, based on the bounding box of the first component and another bounding box that corresponds to another component of the antenna prototype, whether the first component collides with the other component, through a collision detection process. If a collision is detected, the component boundary of the first component is reverted to the recorded current position before the update.

Likewise, steps S801 and S802 of the collision detection mechanism can also be applied to other components of the antenna prototype that affect frequency performance, such as the previously mentioned second and third components.

In an embodiment, the collision detection algorithm uses the following four conditions to determine whether two components (hereinafter referred to as “Component A” and “Component B”) collide:
Condition <I>: A_UR_X>=B_UL_X, where A_UR_X represents the X-coordinate of the upper right vertex of the bounding box of Component A, and B_UL_X represents the X-coordinate of the upper left vertex of the bounding box of Component B;
Condition <II>: B_UR_X>=A_UL_X, where B_UR_X represents the X-coordinate of the upper right vertex of the bounding box of Component B, and A_UL_X represents the X-coordinate of the upper left vertex of the bounding box of Component A;
Condition <III>: B_UL_Y>=A_DL_Y, where B_UL_Y represents the Y-coordinate of the upper left vertex of the bounding box of Component B, and A_DL_Y represents the Y-coordinate of the lower left vertex of the bounding box of Component A; and
Condition <IV>: A_UL_Y>=B_DL_Y, where A_UL_Y represents the Y-coordinate of the upper left vertex of the bounding box of Component A, and B_DL_X represents the Y-coordinate of the lower left vertex of the bounding box of Component B.
   When all of the above conditions (Condition <1>, Condition <2>, Condition <3>, and Condition <4>) are met, it is determined that Component A and Component B collide, and the component being adjusted at that moment should revert to its state before elongation. Conversely, if any of the conditions are not met, it is determined that Component A and Component B have not collided.

FIG. 9 is an architecture diagram of a generative adversarial network (GAN) 900, according to an embodiment of the present disclosure. A generative adversarial network is a model of unsupervised learning that learns through the mutual competition of two neural networks. As shown in FIG. 9, the generative adversarial network 900 consists of a generator network 902 and a discriminator network 905. The task of the generator network 902 is to mimic samples (i.e., real images 903) from the training dataset (or “real image set”) as closely as possible, producing synthetic images 904. The discriminator network 905 is responsible for determining whether the synthetic images 904 generated by the generator network 902 meet the expected criteria, i.e., they are sufficiently similar to the real images 903, although not identical. Next, the training process and operation of the generative adversarial network 900 will be explained.

The discriminator network 905 takes both the real images 903 and the synthetic images 904 as input data and produces a judgment result 906, which indicates the authenticity of these images, through its neural network. More specifically, the judgment result 906 represents the probability that the input data (i.e., the real images 903 and the synthetic images 904) to the discriminator network 905 is real data. During the training process, the discriminator network 905's weights are adjusted iteratively towards optimizing the judgment result 906, i.e., towards enabling the discriminator network 905 to correctly distinguish between real and synthetic images. The judgment result 906 is then feedback to the generator network 902, serving as the basis for adjusting the weights of the generator network 902.

The generator network 902 takes noise 901 as input data and performs certain operations through its neural network to generate synthetic images 904. The noise 901 can be generated from random numbers that follows a normal distribution or a uniform distribution, but the present disclosure is not limited thereto. During the training process, based on feedback from the judgment result 906, the weights of the generator network 902 are adjusted iteratively towards the direction of deceiving the discriminator network 905 by generating synthetic images 904 that are difficult for it to distinguish from real images 903. Simply put, the goal is to make the synthetic images 904 as similar to real images 903 as possible.

Through the mutual adversarial process and parameter adjustments between the generator network 902 and the discriminator network 905, the generator network 902 is trained until the discriminator network 905 finds it difficult to distinguish between the synthetic images 904 generated by the generator network 902 and real images 903. At this moment, the generator network 902 can be considered well-trained. The well-trained generator network 902 can operate independently as a generative model. During its usage phase (such as in step S203 of FIG. 2), it does not need to involve the operation of the discriminator network anymore, nor does it need real antenna images as input to generate antenna prototypes.

The above method can be implemented using computer-executable instructions.

For example, these instructions may include commands and data that cause a general-purpose computer, a special-purpose computer, or a specialized processing device to perform specific functions or sets of functions. Some of the computer resources used may be accessed via a network. For example, computer-executable instructions may be in binary or intermediate format instructions such as assembly language, firmware, or source code.

The antenna design solution provided herein automatically generates antenna prototypes through a generative model, requiring only a small amount of relevant parameters input by the user. Through simulation process and boundary adjustment process, the components of the antenna prototype are adjusted to meet the desired results. This not only saves time spent on human verification and manual adjustments but also allows the antenna prototypes produced by the antenna design system to be more diverse and not limited by human imagination. Therefore, through the antenna design solution provided herein, both the efficiency and innovation of the antenna design process can be significantly enhanced.

The above paragraphs are described with multiple aspects. Obviously, the teachings of the specification may be performed in multiple ways. Any specific structure or function disclosed in examples is only a representative situation. According to the teachings of the specification, it should be noted by those skilled in the art that any aspect disclosed may be performed individually, or that more than two aspects could be combined and performed.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An antenna design system, comprising:
a display unit;
an input unit;
a storage unit, storing a program; and
a processing unit, configured to load the program from the storage unit and run the program to execute steps as follows:
receiving a design parameter set from the input unit;
generating an antenna prototype using a generative model that corresponds to the design parameter set;
causing the display unit to display the antenna prototype;
receiving, from the input unit, one or more tuning parameter sets, among which a first tuning parameter set comprises a first region parameter set and a first frequency band that correspond to a first component of the antenna prototype;
performing a simulation process on the first component of the antenna prototype based on the first frequency band to obtain a frequency offset index of the first component;
checking whether the frequency offset index of the first component satisfies a no-offset condition;
in response to the frequency offset index of the first component not satisfying the no-offset condition, adjusting a scale of the first component based on the frequency offset index of the first component and the first region parameter set; and
iteratively executing the steps of performing the simulation process on the first component and adjusting the scale of the first component until the frequency offset index of the first component satisfies the no-offset condition.

2. The antenna design system as claimed in claim 1, wherein a second tuning parameter set among the tuning parameter sets comprises a second region parameter set and a second frequency band that correspond to a second component of the antenna prototype, and a third tuning parameter set among the tuning parameter sets comprises a third region parameter set and a third frequency band that correspond to a third component of the antenna prototype;
wherein the processing unit further executes steps as follows:
performing the simulation process on the second component of the antenna prototype based on the second frequency band to obtain the frequency offset index of the second component;
checking whether the frequency offset index of the second component satisfies the no-offset condition;
in response to the frequency offset index of the second component not satisfying the no-offset condition, adjusting the scale of the second component based on the frequency offset index of the second component and the second region parameter set;
iteratively executing the steps of performing the simulation process on the second component and adjusting the scale of the second component until the frequency offset index of the second component satisfies the no-offset condition;
performing the simulation process on the third component of the antenna prototype based on the third frequency band to obtain the frequency offset index of the third component;
checking whether the frequency offset index of the third component satisfies the no-offset condition;
in response to the frequency offset index of the third component not satisfying the no-offset condition, adjusting the scale of the third component based on the frequency offset index of the third component and the third region parameter set; and
iteratively executing the steps of performing the simulation process on the third component and adjusting the scale of the third component until the frequency offset index of the third component satisfies the no-offset condition.

3. The antenna design system as claimed in claim 2, wherein the first frequency band is 2.4 GHz, the second frequency band is 5 GHz, and the third frequency band is 6 GHz.

4. The antenna design system as claimed in claim 2, wherein a fourth tuning parameter set among the tuning parameter sets comprises a fourth region parameter set corresponding to a fourth component of the antenna prototype and an impedance matching identifier;
wherein the processing unit further executes the following steps:
performing the simulation process on the antenna prototype to obtain a return loss index of the antenna prototype;
adjusting the scale of the fourth component;
performing the simulation process on the antenna prototype again to obtain another return loss index of the antenna prototype;
determining an adjustment direction by comparing the return loss index with the other return loss index; and
adjusting the scale of the fourth component based on the adjustment direction.

5. The antenna design system as claimed in claim 1, wherein the first component corresponds to a bounding box, wherein the first region parameter set defines a first region, and wherein the processing unit further executes steps as follows to adjust the scale of the first component:
determining an adjustment direction based on the frequency offset index;
calculating a first distance between a component boundary on one side of the bounding box and a region boundary on the same side of the first region;
determining a step size based on the first distance; and
updating the component boundary according to the adjustment direction and the step size.

6. The antenna design system as claimed in claim 5, wherein the processing unit, before updating the component boundary, further records a current position of the component boundary, and after updating the component boundary, further executes steps as follows:
based on the bounding box of the first component and another bounding box that corresponds to another component of the antenna prototype, determining whether the first component collides with the other component through a collision detection process; and
if it is determined that the first component collides with the other component, reverting the component boundary of the first component to the recorded current position before updating.

7. The antenna design system as claimed in claim 5, wherein the processing unit further uses an object detection model to obtain the bounding box that corresponds to the first component in the antenna prototype.

8. The antenna design system as claimed in claim 5, wherein the first tuning parameter set further comprises the bounding box.

9. The antenna design system as claimed in claim 1, wherein the design parameter set further comprises a specification parameter and an environment parameter.

10. The antenna design system as claimed in claim 1, wherein the processing unit further trains a generative adversarial network using a real image set that corresponds to the design parameter set, to obtain the generative model.
